(19) United States
(12) Patent Application Publication
(10) Pub. No.: US 2016/0240730 A1
(43) Pub. Date: Aug. 18, 2016

(54) LIGHT-EMITTING DEVICE AND METHOD FOR MANUFACTURING LIGHT-EMITTING DEVICE

(71) Applicant: MURATA MANUFACTURING CO., LTD., NAGAOKAKYO-SHI (JP)

(72) Inventors: KOJI MURAYAMA, NAGAOKAKYO-SHI (JP); HARUYA MIYATA, NAGAOKAKYO-SHI (JP)

(21) Appl. No.: 15/140,788

(22) Filed: Apr. 28, 2016

Related U.S. Application Data
(63) Continuation of application No. PCT/JP2014/084549, filed on Dec. 26, 2014.

(30) Foreign Application Priority Data
Jan. 9, 2014 (JP) 2014-002392

(51) Int. Cl. H01L 33/06; H01L 33/14

(52) U.S. Cl. CPC H01L 33/06; H01L 33/14; H01L 2933/0033

(57) ABSTRACT

A light-emitting device that includes an anode, a hole injection layer, a hole transport layer, a light-emitting layer, an electron transport layer, and a cathode on a transparent substrate. The light-emitting layer has a plurality of quantum dots dispersed therein, and a hole-transporting material is dispersed in gaps between the quantum dots. To for manufacturing the light-emitting device, a quantum dot dispersing solution having the quantum dots dispersed therein, and a hole-transporting solution containing a soluble hole-transporting material that is soluble in the quantum dot dispersing solution and has a hole transport property are prepared. The hole-transporting solution is applied onto the hole injection layer to form a hole-transporting coating film, and the quantum dot dispersing solution is then applied onto the hole-transporting coating film to dissolve the soluble hole-transporting material in the quantum dot dispersing solution.

### CROSS REFERENCE TO RELATED APPLICATIONS

The present application is a continuation of International application No. PCT/JP2014/084549, filed Dec. 26, 2014, which claims priority to Japanese Patent Application No. 2014-002392, filed Jan. 9, 2014, the entire contents of each of which are incorporated herein by reference.

### FIELD OF THE INVENTION

The present invention relates to a light-emitting device and a method for manufacturing the light-emitting device, and more specifically, a light-emitting device such as an EL element (EL: Electro Luminescence) from which light is emitted by injecting an electric current into a light-emitting layer including a large number of quantum dots composed of a nanoparticle material, and a method for manufacturing the light-emitting device.

### BACKGROUND OF THE INVENTION

Quantum dots that are nanoparticles of 10 nm or less in particle size have excellent performance of confining carriers (electrons, holes), and can thus easily produce excitons by recombination of electrons and holes. For this reason, luminescence from free excitons can be expected, and it is possible to realize luminescence which has a high luminescent efficiency and a sharp emission spectrum. In addition, the quantum dots are able to be controlled in a wide range of wavelengths by using the quantum size effect, and thus attracting attention for applications to light-emitting devices such as EL elements, light emitting diodes (LED), and semiconductor lasers.

It is considered important for this type of light-emitting device to confine and recombine carriers in the quantum dots (nanoparticles) with high efficiency, thereby increasing the luminescent efficiency. Further, a self-assembly (self-organization) method of preparing quantum dots by a dry process is known as a method for preparing the quantum dots.

The self-assembly method is a method of causing gas-phase epitaxial growth of a semiconductor layer under such a specific condition that provides lattice mismatch, and causing self-formation of three-dimensional quantum dots, and for example, when strain is produced from a difference in lattice constant between an n-type semiconductor substrate and a p-type semiconductor substrate and epitaxial growth cannot be caused, a quantum dot is formed at the site with the strain produced.

However, in the self-assembly method, quantum dots are discretely distributed on the n-type semiconductor substrate, and gaps are thus produced between the adjacent quantum dots. For this reason, there is a possibility that holes transported from the p-type semiconductor substrate will be transported toward the n-type semiconductor substrate without being injected into the quantum dots, or electrons transported from the n-type semiconductor substrate will be transported to the p-type semiconductor substrate without being injected into the quantum dots, and there is a possibility of causing a decrease in luminescent efficiency.

Moreover, in the self-assembly method mentioned above, there is a possibility that carriers that are not injected into the quantum dots will recombine to produce luminescence outside the quantum dots. Then, when carriers recombine to produce luminescence outside the quantum dots in such a manner, there is a possibility of causing a decrease in purity of luminescent color. In addition, even when carriers that are not injected into the quantum dots recombine outside the quantum dots, the recombination does not produce luminescence and may result in non-luminescent recombination centers, and in such cases, electrical energy is released as thermal energy without being converted to light energy, and there is thus a possibility of causing a further decrease in luminescent efficiency.

Therefore, Patent Document 1 proposes a semiconductor device including a substrate with a main surface composed of a first semiconductor, a plurality of quantum dots discretely distributed on the main surface, a coating layer composed of a second semiconductor formed on the surface with the quantum dots distributed, and a barrier layer formed from a third semiconductor or an insulating material that is disposed on at least a part of the region without the quantum dots disposed in the plane with the quantum dots distributed and that has a larger bandgap than the bandgaps of the first and second semiconductors.

That is, in Patent Document 1, as illustrated in FIG. 13, n-type GaAs (first semiconductor) is used to form a substrate 101, and p-type GaAs (second semiconductor) is used to form a coating layer 102. In addition, quantum dots 103 composed of InGaAs are discretely distributed on the substrate 101 with the use of a self-assembly method, AlAs (third semiconductor) that has higher bandgap energy than GaAs is further epitaxially grown on the substrate 101 with the use of a molecular beam epitaxy method, and thereafter the AlAs is oxidized to form an insulating barrier layer 104.

In such a manner, in Patent Document 1, the gaps between the quantum dots 103 are filled with the insulating barrier layer 104 to thereby make carriers easy to inject into the quantum dots 103, and promote the recombination of electrons and holes in the quantum dots 103, thereby making an improvement in luminescent efficiency.

On the other hand, Patent Document 2 and Patent Document 3 are known as techniques of preparing colloidal quantum dots by a wet process.

Patent Document 2 proposes a light-emitting device including a light-emitting layer composed of quantum dots and emitting light by recombination of electrons and holes, an n-type inorganic semiconductor layer that transports the electrons to the light-emitting layer, a p-type inorganic semiconductor layer that transports the holes to the light-emitting layer, a first electrode for injecting the electrons into the n-type inorganic semiconductor layer, and a second electrode for injecting the holes into the p-type inorganic semiconductor layer.

In Patent Document 2, as illustrated in FIG. 14, an n-type semiconductor layer 111 and a p-type semiconductor layer 112 are formed from inorganic materials that have a band structure with favorable carrier transport properties, and a quantum dot layer 113 is interposed between the n-type semiconductor layer 111 and the p-type semiconductor layer 112.

Then, electrons transported from the n-type semiconductor layer 111 and holes transported from the p-type semiconductor layer 112 are, due to the tunnel effect, injected into the quantum dot layer 113 through potential barriers between the quantum dot layer 113 and the carrier transport layers (the n-type semiconductor layer 111 and the p-type semiconductor layer 112), thereby improving the efficiency of injecting carriers into the quantum dot layer 113.

In addition, Patent Document 3 proposes a photoelectric conversion device that has a quantum dot layer interposed between a first electrode and a second electrode, where the quantum dot layer is formed from a nanoparticle material with a surface coated with a first surfactant that has a hole transport property and a second surfactant that has an electron transport property.

That is, according to Patent Document 3, as illustrated in FIG. 15, a hole transport layer 123 is formed on an anode (first electrode) 122 formed on a substrate 121, and a light-emitting layer 124 is formed on the hole transport layer 123. Furthermore, an electron transport layer 125 is formed on the light-emitting layer (quantum dot layer) 124, and a cathode (second electrode) 126 is formed on the electron transport layer 125.

In addition, the light-emitting layer 124 is formed from an aggregation of quantum dots (nanoparticle material) 129 of core-shell structure including a core part 127 and a shell part 128, and the quantum dots 129 have surfaces coated with a first surfactant 131 that has a hole transport property and a second surfactant 132 that has an electron transport property.

Then, according to Patent Document 3, when carriers are injected into the anode 122 and the cathode 126 through the application of a voltage, holes of injected carriers are injected into the quantum dots 129 through the first surfactant 131 forming a bulk-hetero network. On the other hand, electrons thereof are also injected into the quantum dots 129 through the second surfactant 132 forming a bulk-hetero network. That is, since the first surfactant 131 can transport only holes and the second surfactant 132 can transport only electrons, the carriers injected into the anode 122 and the cathode 126 through the application of a voltage are efficiently injected into the quantum dots 129 without the recombination of holes with electrons in the surfactants, such that the holes and the electrons recombine in the quantum dots 129 to produce luminescence with high efficiency.

In addition, according to Patent Document 3, a quantum dot dispersing solution having quantum dots dispersed in a non-polar solvent is prepared, and the first surfactant 131 is injected into the quantum dot dispersing solution to coat the surfaces of the quantum dots with the first surfactant 131, thereby preparing a dispersing solution with hole transport property. Then, this dispersing solution is applied onto the hole transport layer 123 to form a film of quantum dot layer with hole transport property, and the first surfactant 131 is then partially substituted with the second surfactant 132 by immersion in a substitution solution containing the second surfactant 132, such that the two types of surfactants coexist which have a hole transport property and an electron transport property.

Patent Document 1: Japanese Patent Application Laid-Open No. 2002-184970 (claim 1, FIG. 1)

Patent Document 2: Japanese Patent Application Laid-Open No. 2006-185985 (claim 1, FIG. 1)

Patent Document 3: International Publication No. WO 2010/065814 (claims 1, 7, paragraphs [0034], [0035], [0089] to [0103], [0123], and the like)

### SUMMARY OF THE INVENTION

However, in Patent Document 1 (FIG. 13), while crystals have few surface defects because the InGaAs constituting the quantum dots 103 are formed by epitaxial growth, the InGaAs has some of In substituted with Ga, and thus makes a little difference in bandgap energy between the InGaAs and the GaAs that forms the substrate 101 and the coating layer 102, and has poor performance of confining carriers.

That is, when the quantum dots are used for a light-emitting layer of a light-emitting device, there is a need to effectively confine holes and electrons in the quantum dots 103, recombine the holes and the electrons in the quantum dots 103, and cause excitons to produce luminescence.

However, in the Patent Document 1, since the difference in bandgap energy is small between the InGaAs that forms the quantum dots 103 and the GaAs that forms the substrate 101 and the coating layer 102, there is a possibility that without recombination of holes transported from a hole transport layer and electrons transported from an electron transport layer in the quantum dots 103, the holes will be transported to the electron transport layer side, and the electrons will be transported to the hole transport layer side, thereby resulting in poor performance of confining carriers into the quantum dots 103.

In addition, in Patent Document 2 (FIG. 14), while the efficiency of injecting carriers into the quantum dot layer 113 is improved by the use of the tunnel effect, it is difficult to effectively confine carriers in the quantum dot layer 113, and thus there has been a problem that the carrier recombination probability is poor and a sufficient luminescent efficiency cannot be obtained.

In addition, according to Patent Document 3 (FIG. 15), in order to achieve the coexistence of the two types of surfactants (first and second surfactants 131, 132) that have a hole transport property and an electron transport property, the first surfactant 131 is partially substituted with the second surfactant 132, and for this reason, an immersion step or the like is required, and there is a possibility of making the manufacturing process cumbersome.

Moreover, according to Patent Document 3, ligands such as a thiol group and an amino group have to be introduced into a hole-transporting material and an electron-transporting material in order to obtain the first and second surfactants, and a cumbersome and special step of synthesizing organic compounds is thus required, and there is a possibility of increasing the cost.

The present invention has been made in view of these circumstances, and an object of the invention is to provide a light-emitting device which can improve the recombination probability in quantum dots at low cost, has favorable luminescent efficiency and purity of luminescent color, and makes it possible to lower the drive voltage, and a method for manufacturing the light-emitting device.

In order to improve the luminescent efficiency of a light-emitting device, it is desirable to improve a carrier balance between electrons injected from an electron transport layer into quantum dots and holes injected from a hole transport layer into the quantum dots, thereby obtaining a favorable recombination probability.

That is, the hole transport layer and the electron transport layer are typically formed from different materials, and thus different in mobility of holes and electrons that pass respectively through the hole transport layer and the electron transport layer. For example, when the electron mobility in the electron transport layer is higher than the hole mobility in the hole transport layer, the injected amount of holes into the quantum dots becomes smaller as compared with the injected amount of electrons therein, thereby failing to obtain a favorable carrier balance, and there is a possibility of causing a decrease in recombination probability between electrons and holes. In addition, when holes and electrons recombine outside the quantum dots due to a difference between electron and hole mobility, there is a possibility of causing a decrease in purity of luminescent color.

Therefore, the present inventors have conducted earnest research in order to improve the carrier balance, and then have found that the presence of a carrier transporting material that is identical in carrier transport property to a carrier transport layer that is lower in carrier mobility, of two types of carrier transport layers that differ in carrier mobility, in a dispersed form between quantum dots can improve the injection efficiency of carriers that are lower in carrier mobility into the quantum dots, thereby making it possible to obtain a light-emitting device which has a recombination probability improved in the quantum dots with the carrier balance improved, has favorable luminescent efficiency and purity of luminescent color, and makes it possible to lower the drive voltage.

The present invention has been made on the basis of the foregoing finding, and a light-emitting device according to the present invention is a light-emitting device including a first carrier transport layer, a second carrier transport layer that is higher in carrier mobility than the first carrier transport layer, and a light-emitting layer sandwiched between the first carrier transport layer and the second carrier transport layer, and emitting light with an electric current injected into the light-emitting layer, and the light-emitting layer has a large number of quantum dots dispersed therein and composed of a nanoparticle material, and a carrier transporting material that is identical in carrier transport property to the first carrier transport layer is present in a dispersed form in gaps between the quantum dots.

In addition, in the light-emitting device according to the present invention, preferably the first carrier transport layer is a hole transport layer, the second carrier transport layer is an electron transport layer, and the carrier transporting material is a hole-transporting material.

Thus, even when the hole mobility in the hole transport layer is lower than the electron mobility in the electron transport layer, the injection of holes into the quantum dots is promoted through the hole-transporting material present in the light-emitting layer, thereby improving the efficiency of injecting holes into the quantum dots. Then, as a result, a light-emitting device can be obtained which has an improved recombination probability of electrons and holes in the quantum dots, has favorable luminescent efficiency and purity of luminescent color, and makes it possible to lower the drive voltage.

In addition, in the light-emitting device according to the present invention, the carrier transporting material is preferably composed of a low-molecular compound.

In addition, in the light-emitting device according to the present invention, the quantum dots preferably each have a surface coated with a surfactant.

That is, even in the use of a bulky surfactant such as a long-chain amine which has no carrier transport property, but has favorable inactivation of surface defects and favorable dispersibility, pairs of holes and electrons can be injected easily into the quantum dots.

In addition, in the light-emitting device according to the present invention, the carrier transporting material is not coordinated on the surfaces of the quantum dots.

Furthermore, in the light-emitting device according to the present invention, the quantum dots each have a core-shell structure including a core part and a shell part.

Then, the light-emitting device mentioned above can be manufactured by preparing a quantum dot dispersing solution having quantum dots dispersed therein, preparing a carrier transporting solution containing a soluble carrier transporting material that is soluble in the quantum dot dispersing solution and has a carrier transport property, applying the carrier transporting solution onto a substrate to form a carrier transporting coating film, and then applying the quantum dot dispersing solution onto the carrier transporting coating film.

That is, a method for manufacturing a light-emitting device according to the present invention includes a dispersing solution preparation step of preparing a quantum dot dispersing solution in which quantum dots composed of a nanoparticle material are dispersed; a carrier transporting solution preparation step of preparing a carrier transporting solution containing a soluble carrier transporting material that has a carrier transport property and is soluble in the quantum dot dispersing solution; and a carrier transport layer-light-emitting layer preparation step of applying the carrier transporting solution onto a substrate to form a carrier transporting coating film, and then applying the quantum dot dispersing solution onto the carrier transporting coating film to dissolve at least a portion of the soluble carrier transporting material such that the carrier transporting material is dispersed in gaps between the quantum dots. With such a method, a carrier transport layer and a light-emitting layer can be prepared simultaneously.

Thus, since the soluble carrier transporting material can dissolve in the quantum dot dispersing solution such that the carrier transporting material is present in a dispersed form between the quantum dots, the carrier transport layer having a reduced layer thickness and the light-emitting layer including the carrier transporting material present in a dispersed form in the gaps between the quantum dots can be prepared simultaneously, thereby making it possible to manufacture a light-emitting device which has favorable luminescent efficiency and purity of luminescent color at low cost.

In addition, in the method for manufacturing a light-emitting device according to the present invention, the soluble carrier transporting material is preferably a low-molecular compound.

Thus, the soluble carrier transporting material can dissolve easily in the quantum dot dispersing solution such that the carrier transporting material is present in a dispersed form in the gaps between the quantum dots.

Furthermore, in the method for manufacturing a light-emitting device according to the present invention, the soluble carrier transporting material is preferably a soluble hole-transporting material.

In addition, in the method for manufacturing a light-emitting device according to the present invention, preferably, the quantum dots each have a surface coated with a surfactant, and the soluble carrier transporting material is not coordinated on the surfaces of the quantum dots.

Thus, since a surfactant that has a carrier transport property is not coordinated on the surfaces of the quantum dots, the need for a synthesis step of introducing a carrier transporting ligand into a surfactant is also eliminated. Furthermore, the need for a substitution step or the like for the coexistence of a plurality of types of surfactants that differ in transport property is also eliminated, and the disengagement of ligands from the surfactants which is associated with the substitution step is also not caused. Therefore, the inactivation of surface defects can be maintained without decrease in the surface coverage of the surfactant, and the film quality is not altered.

In addition, in the method for manufacturing a light-emitting device according to the present invention, the content of the soluble carrier transporting material with respect to the total of the carrier transporting material is preferably 50 wt % or more in the carrier transporting solution, and in particular, the content of the carrier transporting material is preferably 75 to 90% therein.

Thus, even when the carrier transporting solution contains a high-molecular carrier transporting material besides the soluble carrier transporting material, the high-molecular carrier transporting material forms cross-linkages to form a carrier transport layer, while the soluble carrier transporting material dissolves in the quantum dot dispersing solution to form a part of a light-emitting layer. Then, the efficiency of injecting carriers into the quantum dots is improved to provide a favorable recombination probability, thus making it possible to obtain a light-emitting device which has favorable luminescent efficiency and purity of luminescent color, and makes it possible to lower the drive voltage.

With the light-emitting device according to the present invention, the property of transporting carriers that are low in carrier mobility can be improved, thereby making it possible to obtain a light-emitting device which has a recombination probability improved with the improved property of transporting carriers into the quantum dots, has favorable luminescent efficiency and purity of luminescent color, and makes it possible to lower the drive voltage.

With the method for manufacturing a light-emitting device, the soluble carrier transporting material can be dissolved in the quantum dot dispersing solution such that the carrier transporting material is present in dispersed form between the quantum dots, thereby making it possible to prepare a desired light-emitting layer together with the carrier transport layer.

Moreover, there is also no need to cause two types of surfactants that differ in carrier transport property to coexist as in Patent Document 3, and the need for immersion treatment or the like for partially substituting a surfactant is thus eliminated, thereby making it possible to achieve simplification of the manufacturing process.

In addition, since there is no need to use any surfactant that has a carrier transport property, the need for a process of synthesizing an organic compound for the introduction of a carrier transporting ligand is eliminated, thus making it possible to obtain a high-efficiency light-emitting device at low cost.

### BRIEF EXPLANATION OF THE DRAWINGS

FIG. 1 is a cross-sectional view schematically illustrating an embodiment of an EL element as a light-emitting device according to the present invention.

FIG. 2 is a cross-sectional view schematically illustrating a quantum dot that a light-emitting layer contains.

FIGS. 3(A) to 3(C) are manufacturing process diagrams (1/2) illustrating a method for manufacturing the EL element.

FIGS. 4(D) to 4(F) are manufacturing process diagrams (2/2) illustrating a method for manufacturing the EL element.

FIG. 5 is a TEM image for sample number 1.

FIG. 6 is an enlarged TEM image for sample number 1.

FIG. 7 is a TEM image for sample number 4.

FIG. 8 is an enlarged TEM image for sample number 4.

FIG. 9 is a diagram illustrating emission spectra for sample numbers 1 to 4.

FIG. 10 is a diagram illustrating current density characteristics for sample numbers 1 to 4.

FIG. 11 is a diagram illustrating emission spectra for sample numbers 5 to 8.

FIG. 12 is a diagram illustrating current density characteristics for sample numbers 5 to 8.

FIG. 13 is a cross-sectional view for explaining the prior art described in Patent Document 1.

FIG. 14 is a cross-sectional view for explaining the prior art described in Patent Document 2.

FIG. 15 is a cross-sectional view for explaining the prior art described in Patent Document 3.

### DETAILED DESCRIPTION OF THE INVENTION

Next, an embodiment of the present invention will be described in detail.

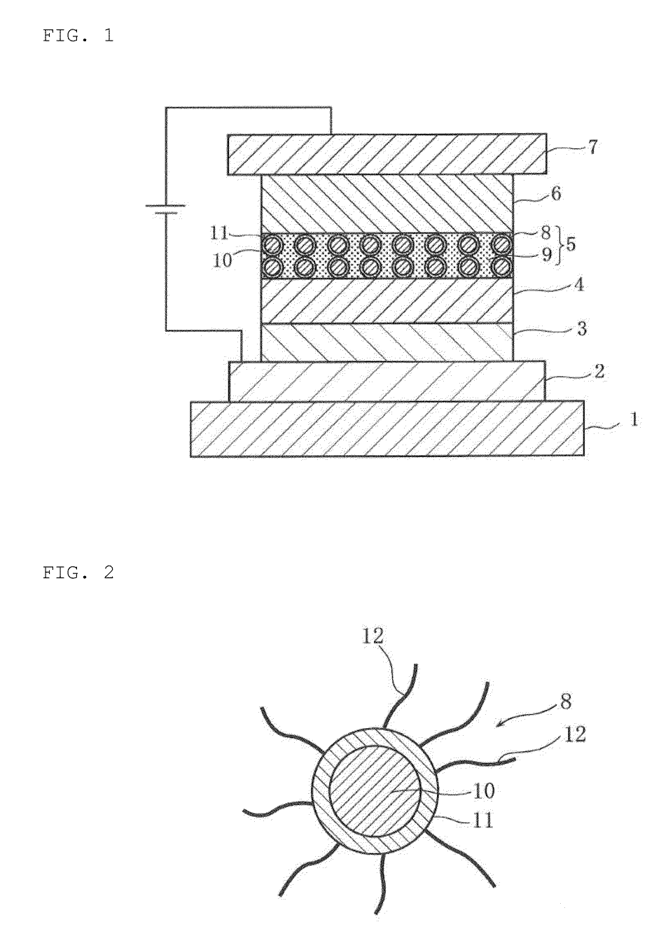

FIG. 1 is a cross-sectional view schematically illustrating an EL element as a light-emitting device according to the present invention.

This EL element has an anode 2 formed on a transparent substrate 1 such as a glass substrate, a hole injection layer 3 and a hole transport layer 4 composed of hole-transporting materials and sequentially formed on the surface of the anode 2, and a light-emitting layer 5 formed on the surface of the hole transport layer 4. Further, an electron transport layer 6 composed of an electron-transporting material is formed on the surface of the light-emitting layer 5, and a cathode 7 is formed on the surface of the electron transport layer 6.

Then, the light-emitting layer 5 includes a large number of quantum dots 8 composed of a nanoparticle material, and a hole-transporting material (carrier transporting material) 9 dispersed in a homogeneous or substantially homogeneous fashion between the quantum dots 8.

The quantum dots 8 are each composed of, as illustrated in FIG. 2, a core-shell structure including a core part 10 and a shell part 11 that protects the core part 10, and the surface of the shell part 11 is coated with a surfactant 12.

The core material that forms the core part 10 is not particularly limited as long as the core material is a material that produces luminescence in a visible light region, and CdZnS, CdS, CdTe, ZnSe, ZnTe, InP, InAs, GaP, GaAs, ZnS:CuInS, ZnS:CuInGaS, Si, Ge, and the like can be used as the core material.

In addition, the shell part 11 is formed mainly for the purpose of inactivating surface defects of the core part 10. For this reason, as the shell material that forms the shell part 11, it is preferable to use a material which has a higher bandgap energy Eg than that of the core material such that the energy level VB1 of the valence band on the basis of the vacuum level is lower than the energy level VB2 of the valence band of the core material.

For example, sulfides such as ZnS and CdS, oxides such as ZnO, SiO₂, TiO₂, and Al₂O₃, nitrides such as GaN and AIN and selenides such as ZnSe and CdSe can be selected appropriately and used as the shell material.

In addition, as the surfactant 12, organic compounds having a bulky polar group, for example, surfactants with a polar group bonded to alkyl groups of long-chain amines such as hexadecylamine (hereinafter, referred to as “HDA”) and octadecylamine, trioctylphosphine, trioctylphosphine oxide, an oleic acid, and a myristic acid can be used preferably from the perspective of dispersibility and further efficient inactivation of surface defects of the core part 10.

That is, when the surface of the shell part 11 is coated with the surfactant 12 having an unbulky ligand, it is difficult to obtain sufficient dispersibility. Moreover, the surfactant 12 is also low in molecular weight, thus low in melting point and boiling point, and often liquid at ordinary temperature. Then, the surfactant 12 which is liquid at ordinary temperature has vigorous molecular motions, and decreases the probability of inactivating surface defects of the core part 10.

Therefore, it is preferable to use, as the surfactant 12, a surfactant having a bulky polar group such as the HDA mentioned above, and it is preferable to have the polar group coordinated as a ligand on the surface of the shell part 11.

It is to be noted that the light-emitting layer 5 is illustrated with the surfactant 12 omitted in FIG. 1.

Then, in the present embodiment, the hole-transporting material 9 is present in a dispersed form in gaps between the quantum dots 8 as mentioned above.

That is, in the present EL element, when a voltage is applied between the anode 2 and the cathode 7, holes injected into the anode 2 are injected through the hole injection layer 3 and the hole transport layer 4 into the quantum dots 8. On the other hand, electrons injected into the cathode 7 are injected through the electron transport layer 6 into the quantum dots 8. Then, in the core parts 10 of the quantum dots 8, the holes and the electrons recombine, thereby producing exciton luminescence.

However, in this case, when there is a difference between the mobility of electrons passing through the electron transport layer 6 and the mobility of holes passing through the hole injection layer 3 and the hole transport layer 4, it is not possible to obtain a desired sufficient luminescent efficiency, and there is further a possibility of causing a decrease in purity of luminescent color. For example, when the electron mobility is higher than the hole mobility, there is a possibility of wastefully consuming electrons due to the lack of holes in the core parts 10, thereby causing a decrease in luminescent efficiency. In addition, there is a possibility that electrons will pass outside the quantum dots 8 without being injected into the quantum dots 8, and reach the hole transport layer 4 to recombine with holes in the hole transport layer 4, thereby causing a decrease in purity of luminescent color. In particular, when the surfactant 12 has a bulky polar group such as HDA as described above, the gaps between the quantum dots 8 become large, and for this reason, there is a possibility that electrons will pass through the gaps between the quantum dots 8 without being supplied into the quantum dots 8, and recombine with carriers in the hole transport layer 4, thereby decreasing the purity of luminescent color.

Therefore, in order to obtain an EL element which has a favorable luminescent efficiency and purity of luminescent color, there is a need to improve a carrier balance such that the injected amount of electrons injected into the core parts 10 is equivalent to the injected amount of holes therein as much as possible.

Thus, according to the present embodiment, the use of a material for the electron transport layer, which has a higher electron mobility than the hole mobility, efficiently injects electrons into the quantum dots 8, and the presence of the hole-transporting material 9 in a dispersed form in the gaps between the quantum dots 8 promotes the injection of holes into the quantum dots 8, thereby improving the carrier balance, and making an improvement in luminescent efficiency. A large amount of holes is injected into the quantum dots 8 in such a manner, and thus the energy barrier also lowers, making it possible to lower the drive voltage. Furthermore, since the hole-transporting material 9 is present in a dispersed form in the gaps between the quantum dots 8, even when the bulky surfactant 12 such as HDA is used, the passage of electrons outside the quantum dots 8 is suppressed, and the electrons are efficiently injected into the quantum dots 8. Then, the electrons effectively recombine, in the quantum dots 8, with holes injected through the hole-transporting material 9, thereby improving the purity of luminescent color.

The material for the electron transport layer for use in the present embodiment is not particularly limited as long as electrons can be transported at high speed from the cathode 7 to the light-emitting layer 5, and for example, a material for the electron transport layer, which has an electron mobility of 10⁻³ to 10⁻⁶ cm²/V·s, can be used preferably.

Specifically, examples of the material for the electron transport layer can include KLET-03 from Chemipro Kasei Kaisha, Ltd., 2,2′,2″-(1,3,5-benzonitrile)-tris(1-phenyl-1-H-benzoimidazole (hereinafter, referred to as “TPBi”) represented by chemical formula (1), 2,9-dimethyl-4,7-diphenyl-1,10-phenanthroline (hereinafter, referred to as “BCP”) represented by chemical formula (2), 2,5-bis(2′,2″-bipyridine-6-yl)-1,1-dimethyl represented by chemical formula (3), 3,4-diphenylsilacyclopentadiene (hereinafter, referred to as “PyPySPyPy”), and triazine-acetylene compounds represented by chemical formula (4).

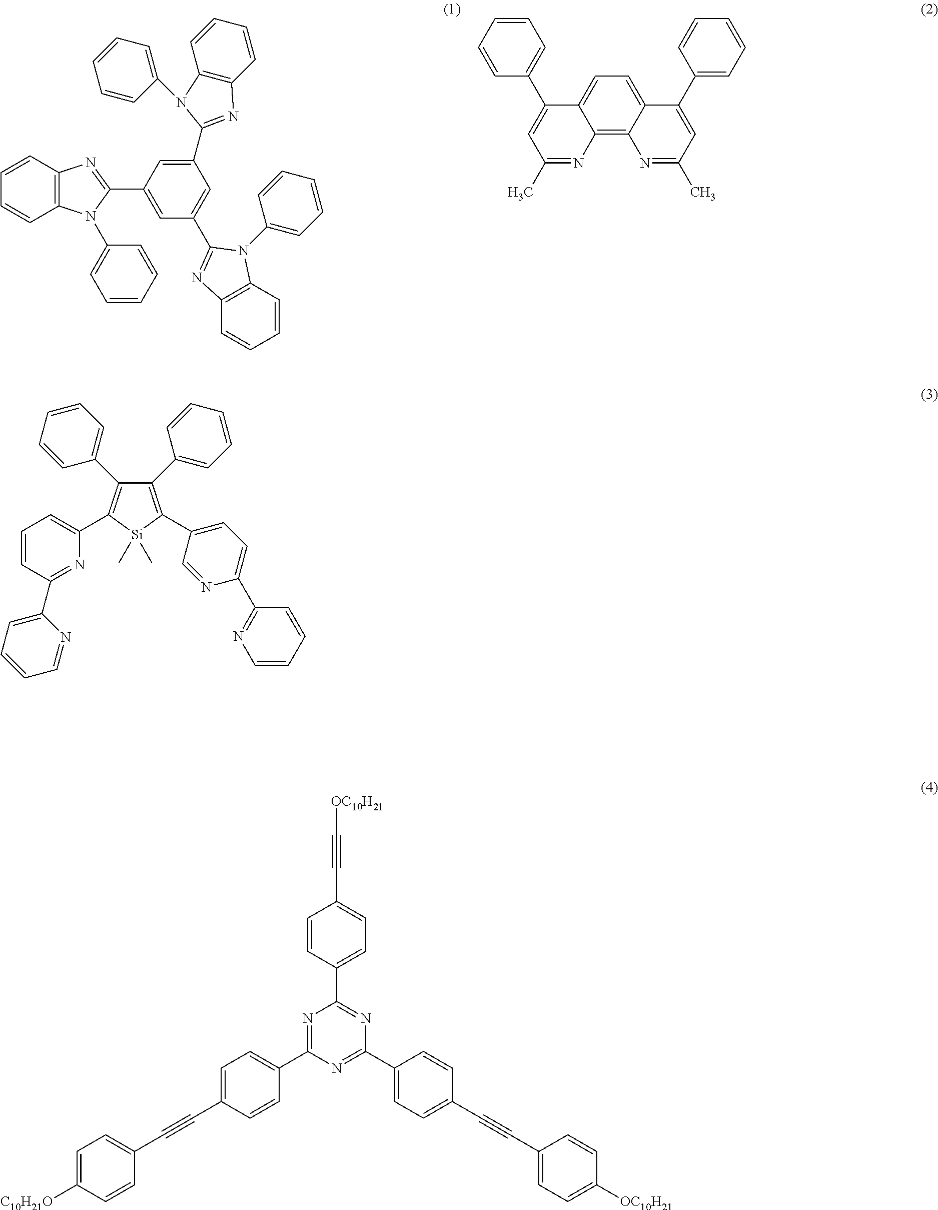

In addition, it is preferable to use, as the hole-transporting material 9 present in the light-emitting layer 5, a low-molecular hole-transporting material that is at least partially soluble in a quantum dot dispersing solution as described later (hereinafter, referred to as a “soluble hole-transporting material”).

Then, examples of such a soluble hole-transporting material can include N,N′-dicarbazoyl-4,4′-biphenyl (hereinafter, referred to as “CBP”) represented by chemical formula (5), N,N′-diphenyl-N,N′-bis(3-methylphenyl)-1,1′-biphenyl-4,4′-diamine (hereinafter, referred to as “TPD”) represented by chemical formula (6), 4,4′-bis[N-(1-naphthyl)-N-phenyl-amino]biphenyl (hereinafter, referred to as “a-NPD”) represented by chemical formula (7), and polyvinyl carbazole (hereinafter, referred to as “PVK”) represented by chemical formula (8).

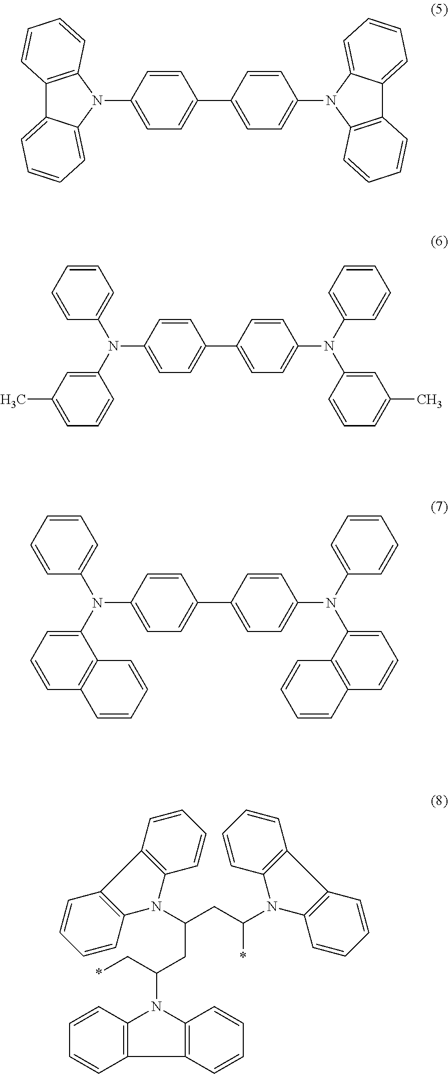

The hole transport layer 4 only needs to contain at least the soluble hole-transporting material described above, and may contain other high-molecular hole-transporting material, for example, poly-TPD and the like. However, in the case of using two or more types of hole-transporting materials, there is a need for the both to be miscible with each other, and thus, for example, when CBP that is soluble in a non-polar solvent such as chlorobenzene is used as the hole-transporting material, there is a need to use a high-molecular hole-transporting material that is dispersible in a non-polar solvent such as poly-TPD.

In addition, the hole injection layer 3 is not particularly limited, but preferably immiscible with the material used for the hole transport layer 4. For example, when CBP or poly-TPD that is dispersible in a non-polar solvent is used as the hole transport layer 4, it is preferable to use, for the hole injection layer 3, a material that is dispersible in a polar solvent (for example, pure water), such as poly(3,4-ethylenedioxythiophene): poly(styrenesulfonate) (hereinafter, referred to as “PEDOT:PSS”).

It is to be noted that the anode 2 and the cathode 7 are also not particularly limited, and for example, an ITO (indium tin oxide) can be used for the anode 2, whereas for example, Al can be used for the cathode 7, and a two-layer structure of LiF/Al can also be adopted.

Then, the present EL element can be manufactured by preparing a quantum dot dispersing solution having quantum dots dispersed therein and a hole-transporting solution containing the soluble hole-transporting material, applying the hole-transporting solution onto the hole injection layer 3 and drying the solution to form a hole-transporting coating film, and then applying the quantum dot dispersing solution and drying the solution.

That is, in the case of preparing the present EL element, just applying, onto the hole transport layer 4, a dispersing solution having the hole-transporting material and quantum dots mixed cannot sufficiently ensure the solubility of the hole-transporting material in the dispersing solution, and it is thus difficult for the hole-transporting material 9 to be present in a dispersed form in the gaps between the quantum dots 8, 8.

For this reason, in the present embodiment, a quantum dot dispersing solution having quantum dots dispersed therein and a hole-transporting solution containing the soluble hole-transporting material in the quantum dot dispersing solution are prepared separately, the hole-transporting solution is applied onto a substrate to form a hole-transporting coating film, and the quantum dot dispersing solution is then applied onto the hole-transporting coating film. That is, when the quantum dot dispersing solution is applied onto the hole-transporting coating film, and thus the soluble hole-transporting material in the hole-transporting coating film dissolves in the quantum dot dispersing solution, thereby making it possible for the hole-transporting material 9 to be present in a dispersed form in the gaps between the quantum dots 8, 8, and making it possible to prepare the hole transport layer 4 and the light-emitting layer 5 simultaneously.

A method for manufacturing the EL element will be described in detail below.

First, a quantum dot dispersing solution is prepared.

While various materials can be used as described above as the quantum dots 8, a case of using CdZnS for the core parts 10 and ZnS for the shell parts 11 will be described as an example in the present embodiment.

That is, first, predetermined amounts of cadmium oxide and zinc acetate are mixed in an oleic acid, and dissolved while being heated to a predetermined temperature (for example, 150° C.) under reduced pressure. Then, this solution is injected into octadecene, and heated to a predetermined temperature (for example, 300° C.) under a reducing atmosphere to prepare a cadmium oxide-zinc acetate mixed solution. On the other hand, a sulfur solution of sulfur dissolved in octadecene is prepared, and the sulfur solution is injected into the cadmium oxide-zinc acetate mixed solution during heating, and further heated for a predetermined period of time (for example, 8 minutes) at a predetermined temperature (for example, 310° C.), thereby obtaining quantum dots of core-shell structure having the core parts 10 of CdZnS and the shell parts 11 of ZnS.

Then, the quantum dots are precipitated with the use of acetone, chloroform, or the like, and a centrifugation operation is carried out to remove a supernatant liquid in the solution. The same operation is repeated more than once, the centrifugation operation is carried out to separate the precipitate, and thereafter, the precipitate is dispersed in a non-polar solvent, for example, toluene while a surfactant such as HDA is added to the precipitate, thereby preparing a quantum dot dispersing solution.

Next, a hole-transporting solution is prepared.

That is, a hole-transporting material containing the soluble hole-transporting material that is soluble at least in the quantum dot dispersing solution is dissolved in a non-polar solvent, thereby preparing the hole-transporting solution.

This hole-transporting solution only needs to contain the soluble hole-transporting material as described above, and may contain a high-molecular hole-transporting material, besides the soluble hole-transporting material.

However, the content of the soluble hole-transporting material with respect to the total amount (soluble hole-transporting material+high-molecular hole-transporting material) of the hole-transporting material is preferably 50 wt % or more from the perspective of obtaining a favorable luminescent efficiency, and preferably 75 wt % or more from the perspective of achieving lowering of the drive voltage.

In addition, the content of the soluble hole-transporting material with respect to the total amount of the hole-transporting material may have an upper limit of 100 wt %, that is, the hole-transporting material may entirely be the soluble hole-transporting material, but is desirably a mixture of the soluble hole-transporting material with a high-molecular hole-transporting material in consideration of the hole injection efficiency, and the upper limit of the content is preferably approximately 90 wt %.

That is, the content of the soluble hole-transporting material with respect to the total amount of the hole-transporting material is not particularly limited, but preferably 50 wt % or more, and more preferably 75 to 90 wt %.

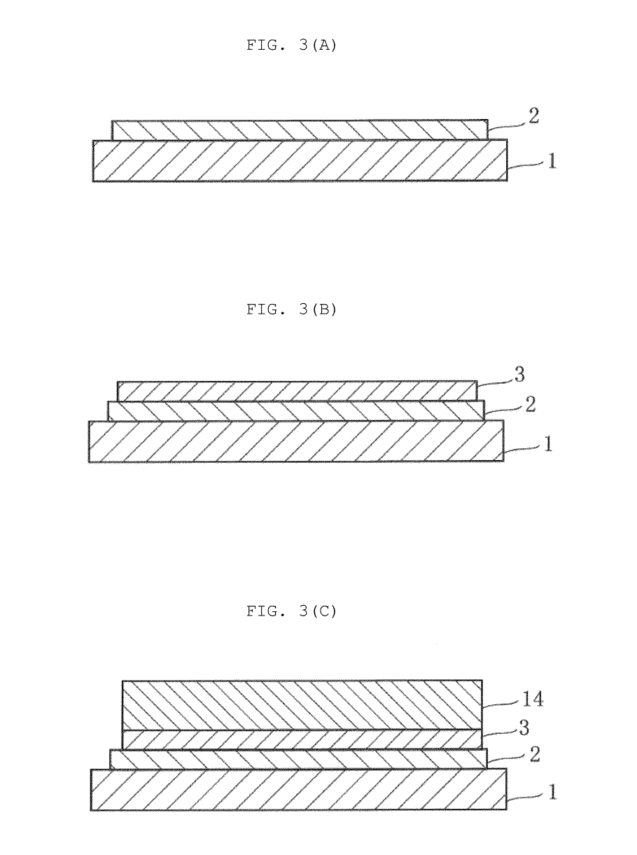

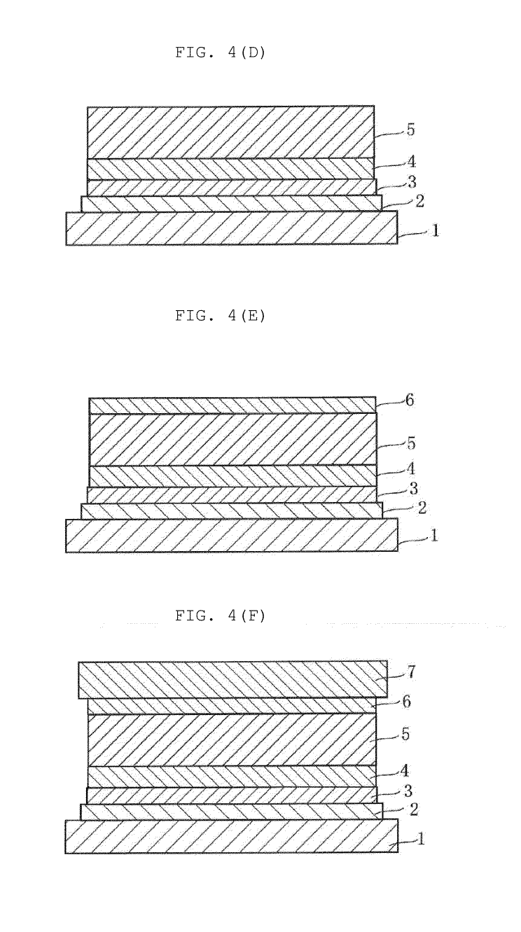

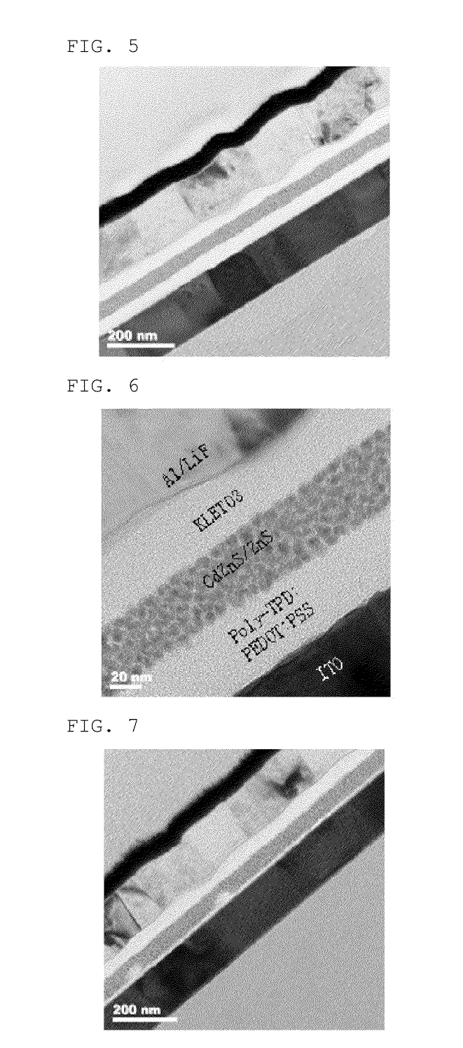

FIGS. 3(A) to 3(C) and 4(D) to 4(F) are manufacturing process diagrams illustrating a method for manufacturing the EL element mentioned above.

First, as illustrated in FIG. 3(A), a conductive transparent material such as an ITO is deposited by a thin-film formation method such as a sputtering method on the transparent substrate 1 such as a glass substrate, and subjected to UV-ozone treatment to form the anode 2 of 100 nm to 150 nm in film thickness.

Next, a hole injection layer solution is prepared, a spin coating method or the like is used to apply the hole injection layer solution onto the anode 2, and the solution is subjected to drying, thereby forming the hole injection layer 3 of 20 nm to 30 nm in film thickness as illustrated in FIG. 3(B).

Next, the hole transporting solution is prepared as mentioned above, a spin coating method or the like is used to apply the hole transporting solution onto the positive electrode injection layer 3, and the solution is subjected to drying, thereby forming a hole-transporting coating film 14 of 60 nm to 70 nm in film thickness as illustrated in FIG. 3(C).

Next, the quantum dot dispersing solution described above is prepared.

Then, a spin coating method or the like is used to apply the quantum dot dispersing solution onto the hole-transporting coating film 14, and the solution is subjected to drying under a reducing atmosphere. On this occasion, the soluble hole-transporting material in the hole-transporting coating film 14 dissolves in the quantum dot dispersing solution to reduce the layer thickness of the hole-transporting coating film 14 to on the order of 40 to 50 nm, thereby forming the hole transport layer 4. Then, simultaneously, the soluble hole-transporting material is present in a dispersed form in the gaps between the quantum dots, thereby preparing the hole transport layer 4 and the light-emitting layer 5 simultaneously as illustrated in FIG. 4(D).

Next, with the use of an electron-transporting material that has a high electron mobility, such as KELT-03 (from Chemipro Kasei Kaisha, Ltd.), the electron transport layer 6 of 50 nm to 70 nm in film thickness is formed on the surface of the light-emitting layer 5 by a thin-film formation method such as a vacuum deposition method, as illustrated in FIG. 4(E).

Then, as illustrated in FIG. 4(F), LiF, Al, or the like is used to form the cathode 7 of 100 nm to 300 nm in film thickness by a thin-film formation method such as a vacuum deposition method, thereby preparing the EL element.

In such a manner, the method for manufacturing the present EL element includes a dispersing solution preparation step of preparing a quantum dot dispersing solution in which the quantum dots 8 composed of a nanoparticle material are dispersed, a hole-transporting solution preparation step of preparing a hole-transporting solution containing a soluble hole-transporting material that has a hole transport property and is soluble in the quantum dot dispersing solution, and a hole transport layer-light-emitting layer preparation step of applying the hole-transporting solution to the hole injection layer 3 to form the hole-transporting coating film 14, and then applying the quantum dot dispersing solution onto the hole-transporting coating film 14 to dissolve at least a portion of the soluble hole-transporting material such that the hole-transporting material 9 is present in a dispersed form in the gaps between the quantum dots 8, and preparing the hole transport layer 4 and the light-emitting layer 5 simultaneously. Thus, the soluble hole-transporting material can be dissolved in the quantum dot dispersing solution such that the hole-transporting material is present in a dispersed form between the quantum dots, thereby making it possible to prepare a desired light-emitting layer together with the hole transport layer.

Moreover, there is also no need to cause two types of surfactants that differ in carrier transport property to coexist as in Patent Document 3, and the need for immersion treatment or the like for partially substituting a surfactant is thus eliminated, thereby making it possible to achieve simplification of the manufacturing process.

In addition, since the soluble hole-transporting material is present in a dispersed form in the gaps between the quantum dots 8 without being coordinated on the surfaces of the quantum dots 8, there is no need to use any surfactant that has a hole-transport property, and the need for a process of synthesizing an organic compound for the introduction of a hole-transporting ligand is thus eliminated, thus making it possible to obtain a high-efficiency light-emitting device at low cost.

Furthermore, the EL element can be manufactured inexpensively and efficiently without the need for more than one cumbersome deposition process as in dry processes.

It is to be noted that the present invention is not limited to the embodiment mentioned above. While the hole-transporting material is present in a dispersed form in the gaps between the quantum dots with the use of the electron-transporting material that has a higher electron mobility than the hole mobility and the hole-transporting material in the embodiment mentioned above, the electron-transporting material may be present in a dispersed form in the gaps between the quantum dots with the use of a hole-transporting material that has a higher hole mobility than the electron mobility and an electron-transporting material. For example, while Alq3 (tris(8-hydroxyquinoline)aluminum) widely known as an electron-transporting material has a low electron mobility of 10⁻⁷ cm²/V·S, it is also possible to combine such an electron-transporting material that has a low electron mobility with a hole-transporting material that has a high hole mobility.

In addition, while the compound semiconductor composed of CdZnS/ZnS is used as each quantum dot in the embodiments described above, the same applies to other compound semiconductors, oxides, and single semiconductors.

In addition, the hole transport layer 4 and the electron transport layer 6 are formed from organic compounds in the embodiment mentioned above, but may be formed from inorganic compounds, thereby making it possible to inexpensively and highly efficiently manufacture a high-quality light-emitting device which has a favorable recombination probability in the quantum dots.

In addition, while the quantum dots of core-shell structure have been described in the embodiment mentioned above, it is obvious that the same applies to a core-shell-shell structure with a shell part of two-layer structure and cases including no shell part.

In addition, it is obvious that the present invention can be used for, besides EL elements, various types of light-emitting devices such as light-emitting diodes, semiconductor lasers, and various types of display devices.

In addition, the electron transport layer 6 is prepared by the dry process using the vacuum deposition method in the embodiments mentioned above, but may be prepared by a wet process such as a spin coating method. However, in this case, there is a need to use a dispersing solvent with the same polarity as that of the dispersing solution used in the immersion step.

Next, an example of the present invention will be specifically described.

### EXAMPLE

[Preparation of Sample]

(Sample Numbers 1 to 4)

Prepared was a quantum dot dispersing solution where quantum dots of core-shell structure with core parts and shell parts formed respectively from CdZnS (LUMO level: 4.4 eV, HOMO level: 7.2 eV) and ZnS (LUMO level: 3.9 eV, HOMO level: 7.4 eV) and shell part surfaces coated with HDA were dispersed in toluene (non-polar solvent).

In addition, CBP (LUNO level: 2.9 eV, HOMO level: 6.0 eV) and poly-TPD (LUNO level: 3.1 eV, HOMO level: 5.4 eV) were prepared respectively as the soluble hole-transporting material and the high-molecular hole-transporting material. Then, the CBP and poly-TPD were weighed such that the content of CBP with respect to the total amount of the CBP and poly-TPD was 0 wt %, 25 wt %, 50 wt %, and 75 wt %, and dissolved in chlorobenzene (non-polar solvent) to prepare respective hole-transporting solutions of sample number 1 (CBP content: 0 wt %), sample number 2 (CBP content: 25 wt %), sample number 3 (CBP content: 50 wt %), and sample number 4 (CBP content: 75 wt %).

Then, a glass substrate of 25 mm×25 mm was prepared, and on the glass substrate, an ITO film (work function: 4.8 eV) was deposited by a sputtering method, and subjected to UV-ozone treatment to prepare an anode of 120 nm in film thickness.

Next, PEDOT:PSS (LUMO level: 3.1 eV, HOMO level: 5.2 eV) was dissolved in pure water as a polar solvent to prepare a hole injection layer solution. Then, a spin coating method was used to apply the hole injection layer solution onto the anode, and the solution was subjected to drying, thereby forming a hole injection layer of 20 nm in film thickness.

Thereafter, a spin coating method was used to apply the hole-transporting solution described above onto the hole injection layer, and the solution was subjected to drying, thereby forming a hole-transporting coating film of 65 nm in film thickness.

Next, a spin coating method was used to apply the quantum dot dispersing solution mentioned above onto the hole-transporting coating film, and the solution was subjected to drying. Specifically, 0.1 mL of the quantum dot dispersing solution was dropped onto the hole-transporting coating film, rotated at rotation frequency: 3000 rpm for 60 seconds, and subjected to drying by heating to 100° C. in a nitrogen atmosphere. Then, the CBP in the hole-transporting coating film thus dissolved in the quantum dot dispersing solution such that the CBP was present in a dispersed form in the gaps between the quantum dots, thereby preparing a hole transport layer having a reduced layer thickness of 45 nm in film thickness and a light-emitting layer of 60 nm in film thickness simultaneously.

Then, KLET-03 (LUMO level: 3.0 eV, HOMO level: 6.7 eV) from Chemipro Kasei Kaisha, Ltd. was deposited on the surface of the light-emitting layer with the use of a vapor deposition method to form an electron transport layer of 50 nm in film thickness.

Finally, LiF/Al (work function: 4.3 eV) was deposited with the use of a vapor deposition method to form a cathode of 100 nm in film thickness, thereby preparing samples of sample numbers 1 to 4.

(Evaluation of Sample)

As for sample number 1 containing no CBP and sample number 4 with the CBP content of 75 wt %, cross sections of the samples were observed with a TEM (transmission electron microscope).

FIG. 5 illustrates a TEM image for sample number 1, and FIG. 6 is an enlarged TEM image of the same sample.

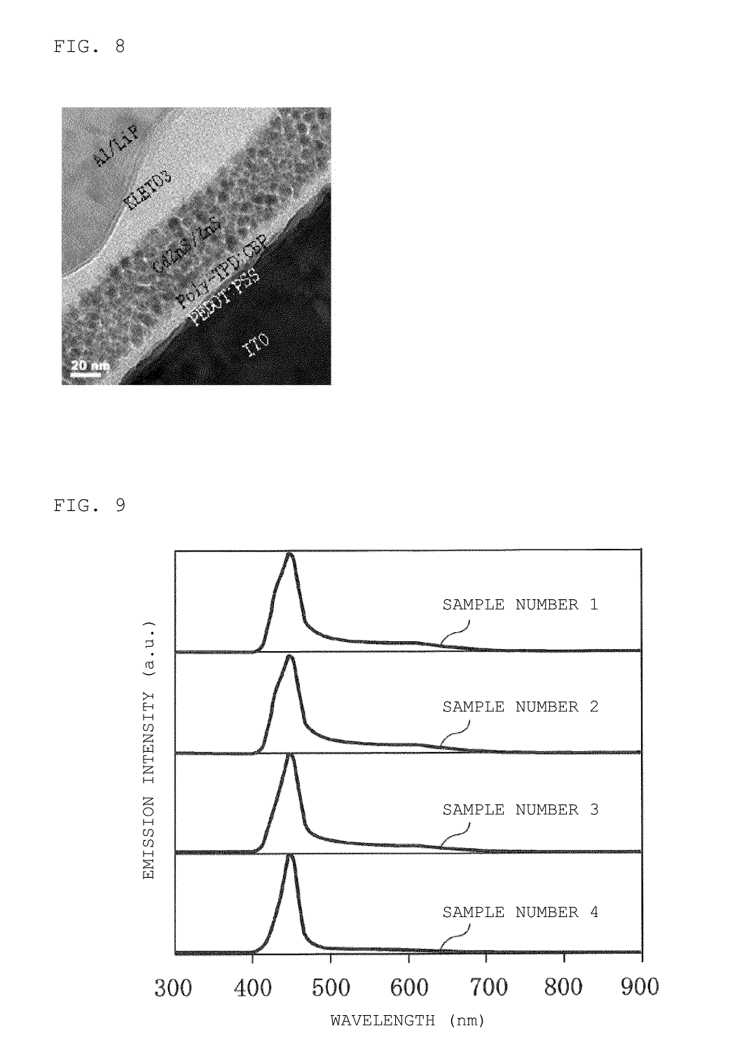

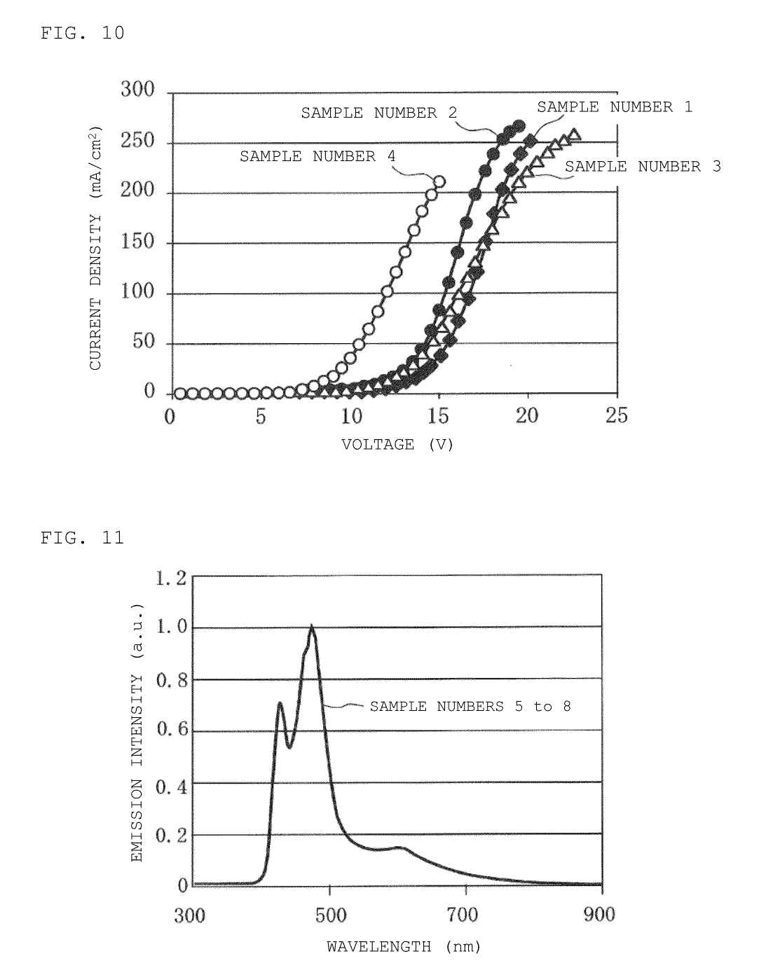

In addition, FIG. 7 illustrates a TEM image for sample number 4, and FIG. 8 is an enlarged TEM image of the same sample.

As is clear from a comparison between FIGS. 5 and 6 and FIGS. 7 and 8, it is found that sample number 4 containing the CBP in the hole-transporting solution has obtained the hole transport layer which is smaller in film thickness and the light-emitting layer which is larger in film thickness, as compared with sample number 1 containing no CBP in the hole-transporting solution. This is considered to be because as for sample number 4, the CBP in the hole-transporting coating film dissolved in toluene in the quantum dot dispersing solution, thereby resulting in that the hole-transporting material was present in a dispersed form in the gaps between the quantum dots, and that the film thickness of the hole transport layer reduced while the film thickness of the light-emitting layer increased.

Next, for each sample of sample numbers 1 to 4, an emission spectrum was measured by the following method.

That is, each sample was placed in an integrating sphere, a direct-current voltage was applied to cause the sample to emit light at a luminance of 100 cd/m² with the use of a constant-current power source (2400 from Keithley Instruments Inc.), the emitted light is collected by the integrating sphere, and an emission spectrum was measured with a multichannel detector (PMA-11 from Hamamatsu Photonics K.K.).

FIG. 9 is a diagram illustrating emission spectra for sample numbers 1 to 4, where the horizontal axis indicates the wavelength (nm), and the vertical axis represents the emission intensity (a.u.). It is to be noted that for each of the emission spectra, the measurement results are normalized between 0 and 1 and illustrated.

In the case of sample number 1, the emission spectrum has a shallow curve made from the position of an intensity peak around 400 to 450 nm that is a range of wavelengths absorbed by the poly-TPD toward around 600 nm. This is considered to be because some of electrons transported through the electron transport layer from the cathode were transported to the hole transport layer without being injected into the quantum dots, and also recombined with electrons in the hole transport layer to produce exciton luminescence. That is, as for sample number 1, it is found that luminescence is produced not only from 400 to 450 nm, but also around 600 nm and a purity of luminescent color is decreased.

In contrast, in the case of sample numbers 2 to 4, as compared with sample number 1, the emission spectra around 400 to 450 nm are steeper, the intensity peaks has a smaller half width, and the emission intensity around 600 nm is also suppressed.

That is, in the case of sample number 2 (CBP content: 25%), as compared with sample number 1, the intensity peak around 400 to 450 nm has a slightly smaller half width, and accordingly, the emission intensity around 600 nm is also slightly suppressed.

In the case of sample number 3 (CBP content: 50%), as compared with sample number 1, the intensity peak around 400 to 450 nm has a further smaller half width, and accordingly, the emission intensity around 600 nm is also further suppressed.

In the case of sample number 4 (CBP content: 75%), as compared with sample number 1, the emission spectrum around 400 to 450 nm is steeper, the intensity peak also has a clearly smaller half width, and there is almost no luminescence around 600 nm.

In such a manner, as the content of CBP in the hole-transporting material increases, the emission spectrum around 400 to 450 nm becomes steeper, and the half width of the intensity peak also becomes smaller, and the luminescence around 600 nm can be suppressed. In particular, it is found that a favorable purity of luminescent color is obtained with the CBP content of preferably 50% or more, more preferably 75% or more.

Next, for each sample of sample numbers 1 to 4, with the use of the multichannel detector mentioned above, direct-current voltage was applied in steps to measure the current density.

FIG. 10 is a diagram illustrating the relationship between the applied voltage and the current density, where the horizontal axis indicates the voltage (V), and the vertical axis indicates the current density (mA/cm²). In the figure, a mark ♦ indicates sample number 1 (CBP content: 0 wt %), a mark indicates sample number 2 (CBP content: 25 wt %), a mark Δ indicates sample number 3 (CBP content: 50 wt %), and a mark ◯ indicates sample number 4 (CBP content: 75 wt %).

As is clear from FIG. 10, sample number 4 with the CBP content of 75 wt % that is the soluble hole-transporting material has succeeded in significantly lowering the drive voltage, as compared with sample number 1 containing no CBP.

That is, it has been confirmed that the content of the soluble hole-transporting material with respect to the total amount of the hole-transporting material is preferably 75% or more from the perspective of achieving lowering of the drive voltage.

### Comparative Example

Samples of sample numbers 5 to 8 were prepared in accordance with the same method and procedure as with the samples mentioned above, except that the quantum dot dispersing solutions contained CBP at 0 mmol/L, 0.01 mmol/L, 0.1 mmol/L, and 1 mmol/L, and the hole transport layer solutions contained no CBP.

Next, for each sample of sample numbers 5 to 8, an emission spectrum was measured in accordance with the same method and procedure as described above.

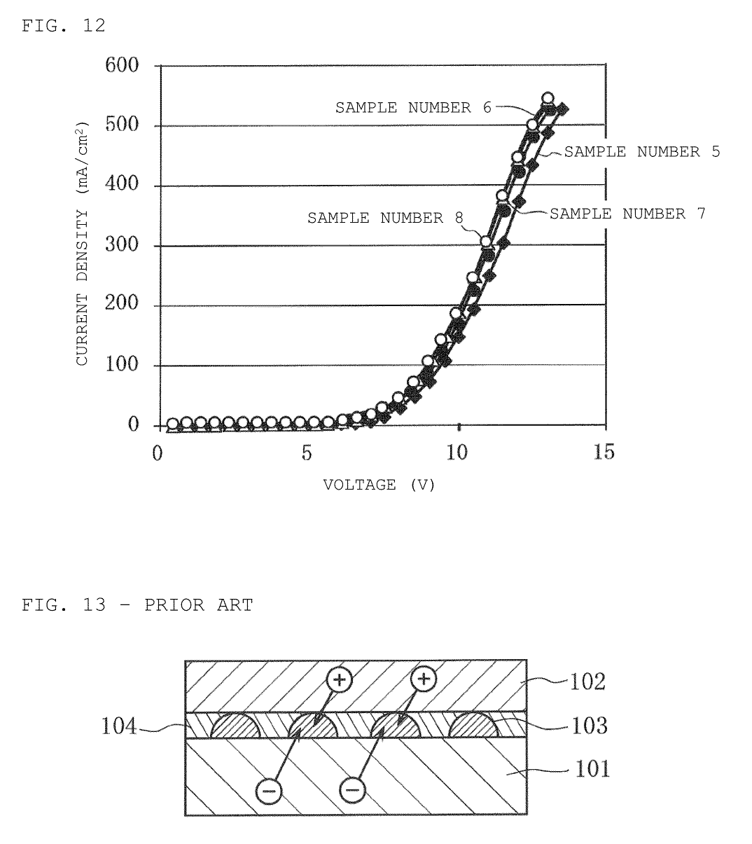

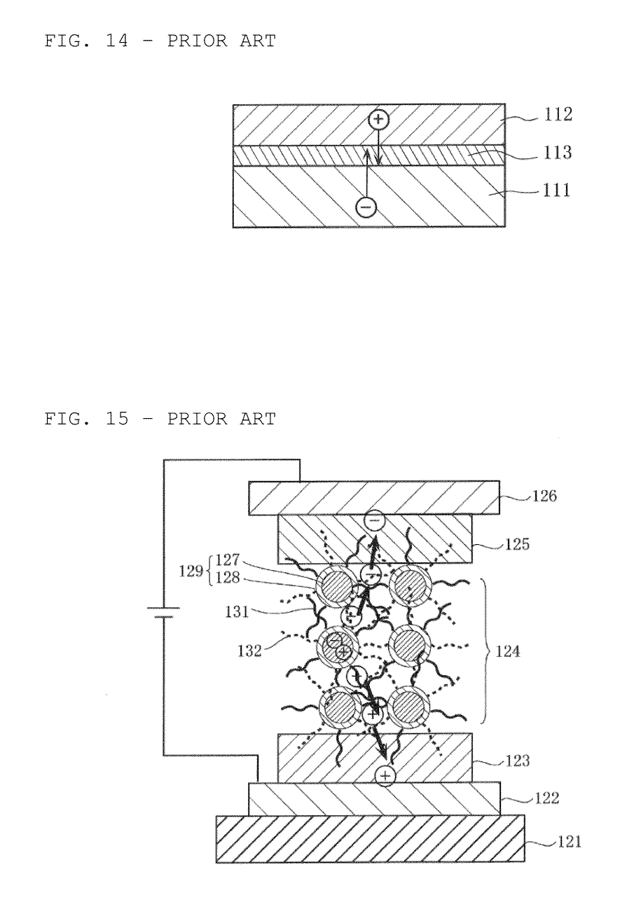

FIG. 11 is a diagram illustrating emission spectra for sample numbers 5 to 8, where the horizontal axis indicates the wavelength (nm), and the vertical axis represents the emission intensity (a.u.). It is to be noted that for the emission spectra, the measurement results are normalized between 0 and 1 and illustrated.

As is clear from FIG. 11, the cases of forming the light-emitting layer with the quantum dot dispersing solution containing CBP have substantially the same emission spectrum as in the case of the quantum dot dispersing solution containing no CBP, and in each case, there is luminescence around 400 to 450 nm that is a range of wavelengths absorbed by the poly-TPD and 600 nm. That is, it has been found that holes and electrons also recombine in the hole transport layer to produce exciton luminescence, thereby decreasing the purity of luminescent color.

From the foregoing, it has been confirmed that the luminescent efficiency or the purity of luminescent color is not improved even when the quantum dot dispersing solution contains CBP, and the luminescent efficiency and the purity of luminescent color are improved with the hole-transporting solution containing CBP as in the example described above.

Next, for each sample of sample numbers 5 to 8, the current density was measured in accordance with the same method and procedure as described above.

FIG. 12 is a diagram illustrating the relationship between the applied voltage and the current density, where the horizontal axis indicates the voltage (V), and the vertical axis indicates the current density (mA/cm²). In the figure, a mark ♦ indicates sample number 5 (CBP content: 0 mmol/L), a mark indicates sample number 6 (CBP content: 0.01 mmol/L), a mark A indicates sample number 7 (CBP content: 0.1 mmol/L), and a mark 0 indicates sample number 8 (CBP content: 1 mmol/L).

As is clear from FIG. 12, it has been confirmed that when the light-emitting layer is formed with the quantum dot dispersing solution containing CBP, the drive voltage is almost unchanged as compared with a case of the quantum dot dispersing solution containing no CBP.

The efficiency of injecting holes and electrons into the quantum dots is improved to improve the luminescent efficiency and the purity of luminescent color, thereby making it possible to realize a light-emitting device such as an EL element which is capable of low-voltage driving.

### DESCRIPTION OF REFERENCE SYMBOLS

4 hole transport layer (first carrier transport layer)

5 light-emitting layer

8 quantum dot

9 hole-transporting material (carrier transporting material)

10 core part

11 shell part

12 surfactant

14 hole-transporting coating film (carrier transporting coating film)

1. A light-emitting device comprising:
a first carrier transport layer;
a second carrier transport layer that is higher in carrier mobility than the first carrier transport layer; and
a light-emitting layer between the first carrier transport layer and the second carrier transport layer, the light-emitting layer having a plurality of quantum dots dispersed therein and a carrier transporting material dispersed in gaps between the quantum dots, and the carrier transporting material has identical carrier transport properties to those of the first carrier transport layer.

2. The light-emitting device according to claim 1, wherein the quantum dots are composed of a nanoparticle material.

3. The light-emitting device according to claim 1, wherein the first carrier transport layer is a hole transport layer, the second carrier transport layer is an electron transport layer, and the carrier transporting material is a hole-transporting material.

4. The light-emitting device according to claim 3, wherein the carrier transporting material is a soluble hole-transporting material.

5. The light-emitting device according to claim 4, wherein the soluble hole-transporting material is selected from the group consisting of N,N′-dicarbazoyl-4,4′-biphenyl, N,N′-diphenyl-N,N′-bis(3-methylphenyl)-1,1′-biphenyl-4,4′-diamine, 4,4′-bis[N-(1-naphthyl)-N-phenyl-amino]biphenyl, and polyvinyl carbazole.

6. The light-emitting device according to claim 1, wherein the carrier transporting material is a soluble hole-transporting material.

7. The light-emitting device according to claim 6, wherein the soluble hole-transporting material is selected from the group consisting of N,N′-dicarbazoyl-4,4′-biphenyl, N,N′-diphenyl-N,N′-bis(3-methylphenyl)-1,1′-biphenyl-4,4′-diamine, 4,4′-bis[N-(1-naphthyl)-N-phenyl-amino]biphenyl, and polyvinyl carbazole.

8. The light-emitting device according to claim 1, wherein the quantum dots each have a surface coated with a surfactant.

9. The light-emitting device according to claim 1, wherein the carrier transporting material is not coordinated on surfaces of the quantum dots.

10. The light-emitting device according to claim 1, wherein the quantum dots each have a core-shell structure including a core part and a shell part.

11. A method for manufacturing a light-emitting device, the method comprising:
preparing a quantum dot dispersing solution;
preparing a carrier transporting solution containing a soluble carrier transporting material that has a carrier transport property and is soluble in the quantum dot dispersing solution; and
applying the carrier transporting solution onto a substrate to form a carrier transporting coating film, and then applying the quantum dot dispersing solution onto the carrier transporting coating film to dissolve at least a portion of the soluble carrier transporting material such that the carrier transporting material is dispersed in gaps between the quantum dots.

12. The method for manufacturing a light-emitting device according to claim 11, wherein the method simultaneously forms a carrier transport layer and a light-emitting layer.

13. The method for manufacturing a light-emitting device according to claim 11, wherein the quantum dots are composed of a nanoparticle material.

14. The method for manufacturing a light-emitting device according to claim 11, wherein the soluble carrier transporting material is a soluble hole-transporting material.

15. The method for manufacturing a light-emitting device according to claim 14, wherein the soluble hole-transporting material is selected from the group consisting of N,N′-dicarbazoyl-4,4′-biphenyl, N,N′-diphenyl-N,N′-bis(3-methylphenyl)-1,1′-biphenyl-4,4′-diamine, 4,4′-bis[N-(1-naphthyl)-N-phenyl-amino]biphenyl, and polyvinyl carbazole.

16. The method for manufacturing a light-emitting device according to claim 11, wherein the quantum dots each have a surface coated with a surfactant, and the soluble carrier transporting material is not coordinated on the surface of the quantum dots.

17. The method for manufacturing a light-emitting device according to claim 11, wherein a content of the soluble carrier transporting material with respect to a total of the carrier transporting material is 50 wt % or more in the carrier transporting solution.

18. The method for manufacturing a light-emitting device according to claim 17, wherein the content of the carrier transporting material is 75 to 90 wt %.
